(19) United States
(12) Patent Application Publication
(10) Pub. No.: US 2007/0119704 A1
(43) Pub. Date: May 31, 2007

(54) Method for sputtering a multilayer film on a sheet workpiece at a low temperature

(76) Inventors: Jau-Jier Chu, Yangmei Township (TW); Hsu-Fu Hung, Yangmei Township (TW); I-Wen Lee, Yangmei Township (TW); Chien-Min Weng, Yangmei Township (TW); Tzu-Wen Chu, Yangmei Township (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/698,904

(22) Filed: Jan. 29, 2007

Related U.S. Application Data
(63) Continuation-in-part of application No. 11/289,289, filed on Nov. 30, 2005.

(51) Int. Cl. C23C 14/00

(52) U.S. Cl. 204/192.15

(57) ABSTRACT

A method for sputtering a multilayer film on a sheet workpiece at a low temperature of the present invention has the following steps: employing plasma to modify a surface of a sheet workpiece, providing a reciprocating sputtering process to deposit metal oxide layers or semiconductor oxide layers on the sheet workpiece, preheating the sheet workpiece and providing a reciprocating ITO sputtering process to sputter ITO transparent conductive layers on the sheet workpiece. The film sputtering process of the sheet workpiece employs continuously connecting work line and controls delay time between the sputtering units to deposit a film with a predetermined thickness on the sheet workpiece.

### REFERENCE TO RELATED APPLICATIONS

This Patent Application is a Continuation-in-Part of patent application Ser. # 11/289,289, filed 30 Nov. 2005, currently pending.

### BACKGROUND OF THE INVENTION

1. Field of the Invention

The present invention relates to a method for sputtering a multilayer film on a sheet workpiece at a low temperature, and more particularly to a method based on the characteristic that sheet workpieces are ready to dispose in a continuous product line. Arranges continuous manufacturing process, employs plasma to modify surfaces of the workpieces, and combines with a conventional sputtering machine, thereby achieving convenience of installation and mass production of advanced material.

2. Description of the Related Art

The indium tin oxide (ITO) advanced multilayer film panel is very important in the supply of photoelectric raw and processed material. Along with the developing of photoelectric industry, it is also important to keep a low defects, controllable-manufacturing, costs-reducing and high-speed production method. The applications of manufacturing an (ITO) advanced multilayer film panel are related to many kinds of photoelectric products, such as an LCD, an OLED display, a field emission display, and touch panel. Although there are different applications of the ITO advanced multilayer film panel, the requirement of quality of each industry is the same. It is well known that from the substrate of the photoelectric industry to the raw and processed material of a transparent electrode, almost all processes of the advanced panel are based on the ITO advanced multilayer film. The ITO advanced multilayer film panel and other electronic modules are assembled together in a linking structure, thereby forming an electronic product for achieving a given design function. The ITO advanced multilayer film panel must have three functions, power transportation, signal transportation, and transparency.

FIG. 1 is a schematic view of a reel-type manufacturing process of a conventional ITO multilayer film panel. A raw material roll 10a, a plasma 30a film sputtering process (ITO or oxide layer in general), and a material collection roll 20a are deposited in sequence. When the multilayer film sputtering process is done, a long product line is required. A material tensile force between the raw material roll 10a and the material collection roll 20a is insufficient. So a tensile wheel is added. However, the tensile wheel may deflect and lock the material strip. Thus, the conventional multilayer film sputtering method not only has a problem that equipment is not easy to configure, but also has a problem of maintenance. SO the roll to roll sputtering process is preferred to the coating system with a few film layers. It is necessary to use a quick and reliable method to manufacture the ITO advanced multilayer film panel, particularly when manufacturing a basic material of the macromolecule type, such as transparent polyterephthalate (PET) or acryl (polymethyl methacrylate, PMMA).

However, the polymer workpiece is with poor heat resistance, the processing temperature has to be lower than those of sputtering films on glass substrates. In the processes of prior art, the heat generated by plasma is easily accumulated on the workpiece, and causing a heat damage on polymer substrate.

### SUMMARY OF THE INVENTION

Accordingly, an object of the present invention is to provide a method for sputtering a multilayer film on a sheet workpiece at a low temperature to prevent the substrate of the macromolecule type, such as PET and PMMA from the heat damage. The temperature of the process in the present invention is 60 to 150 degree C. and is lower than the maximum temperature limitation of the macromolecule type substrates.

Another object is that the present invention provides a method for sputtering a multilayer film on a sheet workpiece at a low temperature to improve the physical and optical properties of the indium tin oxide (ITO) film.

To achieve the above-mentioned objects, the present invention provides a method for sputtering a multilayer film on a sheet workpiece at a low temperature. The present invention provides reciprocating sputtering processes to deposit films on the workpiece. The reciprocating sputtering processes is provided to move a workpiece reciprocatingly in the coating chamber and decreases the accumulating heat on the workpiece.

To achieve the above-mentioned objects, the present invention provides a method for sputtering a multilayer film on a sheet workpiece at a low temperature. Heating devices are employed to slightly increase the temperature of the workpiece before ITO sputtering layer to improve the crystallization of the ITO film.

The method for sputtering a multilayer film on a sheet workpiece at a low temperature of the present invention includes the following steps: employing plasma to modify a surface of a sheet workpiece; providing reciprocating sputtering processes to deposit metal oxide layers or semiconductor oxide layers on the sheet workpiece; preheating the sheet workpiece to a predetermined temperature; providing a reciprocating sputtering process to sputter indium tin oxide (ITO) transparent conductive layers on the sheet workpiece. The film sputtering process of the sheet workpiece employs continuously connecting work line, and controls delay time of the workpiece in the reciprocating sputtering process to deposit a film with a predetermined thickness.

### BRIEF DESCRIPTION OF THE DRAWINGS

Other objects, advantages and novel features of the present invention will be drawn from the following detailed embodiments of the present invention with attached drawings, in which:

FIG. 1 is a schematic view showing a conventional film sputtering product line;

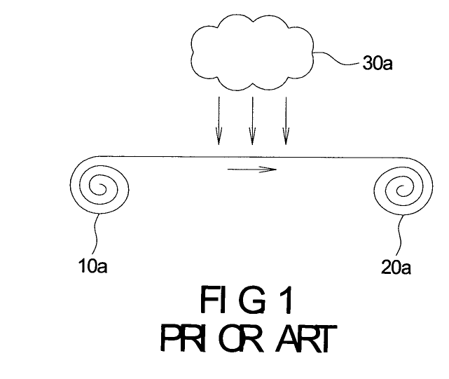

FIG. 2A is a schematic view showing a front portion of a product line of an ITO advanced multilayer film panel manufactured by the method of the present invention;

FIG. 2B is a schematic view showing a rear portion of a product line of an ITO advanced multilayer film panel manufactured by the method of the present invention;

FIG. 3A is a table showing manufacture data of a front portion of a product line of the ITO advanced multilayer film panel manufactured by the method of the present invention;

FIG. 3B is a table showing manufacture data of a rear portion of a product line of the ITO advanced multilayer film panel manufactured by the method of the present invention; and

FIG. 4 is a flow chart of the method of the present invention.

### DETAILED DESCRIPTION OF PREFERRED EMBODIMENTS

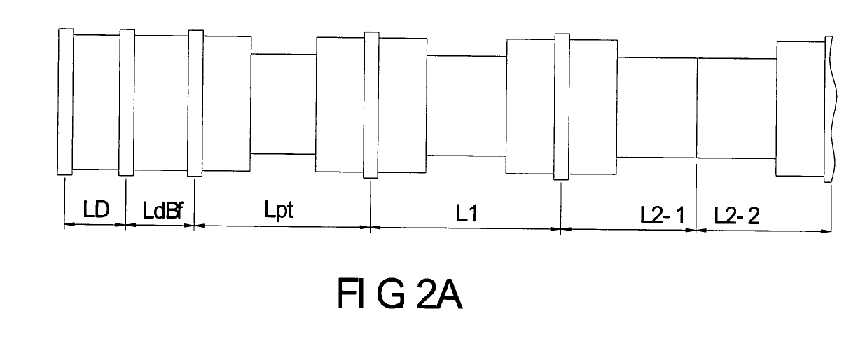

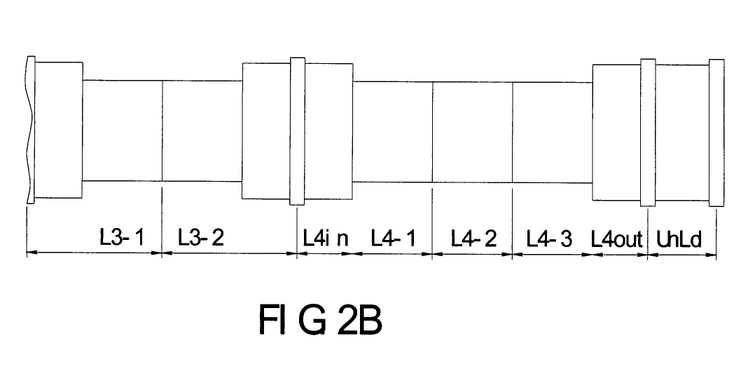

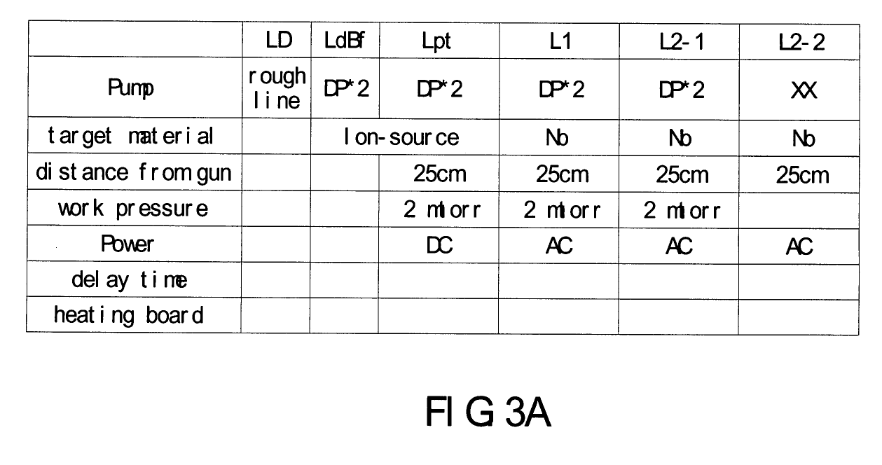

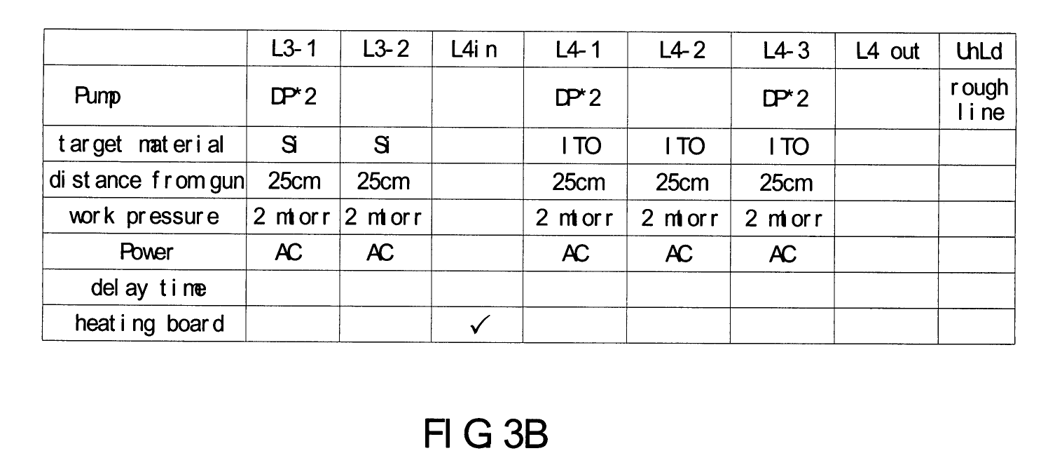

Referring to FIGS. 2A, 2B, 3A and 3B, an embodiment of the present invention is shown. The goal is to manufacture continuously sheet workpieces made from plastic board (PET or PMMA). The continuously connecting work line has a plurality of sputtering units and a plurality of buffer chambers, and each sputtering unit is disposed between two buffer chambers. As shown in figures, some sputtering units have more than two coating chambers, and the off-board coating chambers of the sputtering unit are backup chambers when the working coating chamber is broken down.

The continuous manufacturing process includes steps of modifying a surface of a sheet workpiece with plasma (steps LdBf and Lpt), and increasing the roughness of the workpiece surface by ion bombardment. The modified surface of the workpiece can improve the adhesion between the workpiece and the following-mentioned films. As to a diagram of the relationship between the steps for the programming process of the ITO advanced multilayer film panel and specifications of the equipment, at the beginning, the plastic board enters a feed-in step (LD, LOAD), and then enters processing line (Lpt to L3-2) of sputtering metal oxide layers or semiconductor oxide layers on the sheet workpiece. It can be observed from the drawings that in this embodiment the silicon oxide layers (target materials are silicon, but an oxide film is formed during sputtering) and niobium oxide layers (the target material is niobium but the oxide film is formed during sputtering) are sputtered. In the above-mentioned sputtering process, buffer chambers are disposed on the each end of the coating chamber, and the workpiece moves reciprocatingly between the two buffer chambers to repeatedly deposit layers on the surface of the workpiece. Moreover, a delay time of the workpiece moving reciprocatingly between the two buffer chambers is controlled to deposit a film with a predetermined thickness. The reciprocating sputtering processes is provided to accumulate less heat generating by plasma on the workpiece and prevent the substrate of the macromolecule type, such as PET and PMMA from the heating damage.

In a latter process, ITO transparent conductive layers (L4in to L4out) are sputtered. A higher temperature can improve the crystallization of ITO film deposited, but the heating temperature has to be controlled under the maximum temperature limitation of the polymer workpiece. Thus, a buffer chamber L4in having a heating device, such as a heating board is provided to raise the temperature of the workpiece up to 60 degrees C. to 150 degrees C. prior to the ITO sputtering process. By applying the heating devices, the ITO film is more crystallized. However, the temperature of the workpiece has to be controlled to protect the substrate. After the preheating process, the workpiece is transferred into the ITO reciprocating sputtering process (L4-1 to L4-3), the ITO film is formed on the workpiece with a predetermined thickness by controlling the delay time of the workpiece between the L4in and L4out chamber. By the manner, there is a multilayer film sputtered on the workpiece.

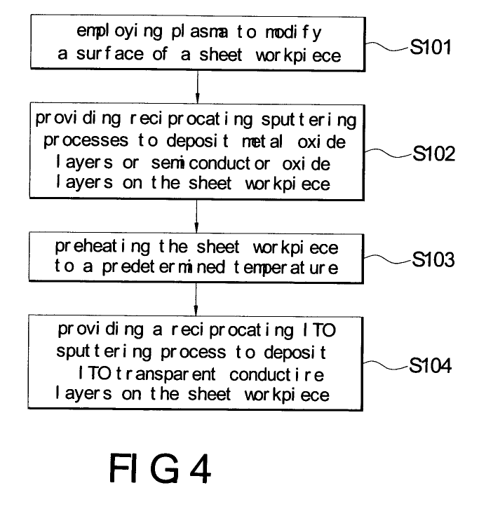

Referring to FIG. 4, a method for sputtering a multilayer film on a sheet workpiece of the present invention includes the following steps: employing plasma to modify a surface of a sheet workpiece (S101), providing reciprocating sputtering processes to deposit metal oxide layers or semiconductor oxide layers on the sheet workpiece (S102), preheating the workpiece (S103) and sputtering ITO transparent conductive layers on the sheet workpiece (S104). The sputtering process of the sheet workpiece employs continuously connecting work line, thereby controlling delay time between the buffer chambers to deposit a film with a predetermined thickness. The sheet workpiece is made from a macromolecular material.

The details of the embodiment of the present invention may be varied as follows. The film sputtering process of the sheet workpiece is maintained within a predetermined range of cleaning levels (sputtering requires a clean surface of the workpiece). Plasma is provided to modify the surface of the workpiece to be clean and rough to enhance the adhesion between the workpiece and the deposited films. Reciprocating sputtering processes are provided to deposit metal oxide layers or semiconductor oxide layers on the workpiece and controlling the delay time to get films with predetermined thickness. The sheet workpiece is transferred between the film sputtering units by a conveyer belt or an automatic cart (similar to the semiconductor process). The metal oxide includes niobium oxide and the semiconductor oxide includes silicon oxide. Prior to all of the manufacture steps, a step of forming the sheet workpiece is further provided (integrating an upper process to control the size of the workpiece).

Accordingly, the continuously connecting work line has a plurality of sputtering units and a plurality of buffer chambers, and each end of the sputtering units connects one buffer chamber. At least one sputtering units have more than one coating chambers and when a working coating chamber is failed to work, another working coating chamber maintains the work line to operate.

The method of the present invention has the following advantages: 1) a reciprocating sputtering processes are provided to sputtering multilayer on the workpiece; 2) a delay time between buffer chambers is controlled to deposit a film with a predetermined thickness; and 3) a preheating process is provided to improve the crystallization of the ITO film.

It is understood that the invention may be embodied in other forms without departing from the spirit thereof. Thus, the present examples and embodiments are to be considered in all respects as illustrative and not restrictive, and the invention is not to be limited to the details given herein.

What is claimed is:

1. A method for sputtering a multilayer film on a sheet workpiece, comprising the following steps:
employing plasma to modify a surface of a sheet workpiece;
providing at least one reciprocating sputtering processes to deposit at least one metal oxide layers or semiconductor oxide layers on the sheet workpiece; preheating the sheet workpiece to a predetermined temperature;
providing a reciprocating indium tin oxide (ITO) sputtering process to sputter ITO transparent conductive layers on the sheet workpiece; and
wherein the film sputtering process of the sheet workpiece employs a continuously connecting work line, thereby controlling a delay time of the workpiece in the reciprocating sputtering process to deposit a film with a predetermined thickness, and the sheet workpiece is made from a macromolecular material;
wherein a heating device is provided prior to the ITO sputtering process to preheat the sheet workpiece.

2. The method as claimed in claim 1, wherein the continuously connecting work line has a plurality of sputtering units and a plurality of buffer chambers, and each sputtering unit is disposed between two buffer chambers.

3. The method as claimed in claim 2, wherein the sputtering units have working coating chambers, and the other coating chambers of the sputtering unit are backup chambers when one working coating chamber is broken down.

4. The method as claimed in claim 1, wherein plasma is provided to modify the surface of the sheet workpiece to be clean and rough.

5. The method as claimed in claim 1, wherein the predetermined temperature is 60 degrees C. to 150 degrees C.

6. The method as claimed in claim 1, wherein the heating device is a heating board.

7. The method as claimed in claim 1, wherein the film sputtering process of the sheet workpiece is maintained within a predetermined range of cleaning levels.

8. The method as claimed in claim 1, wherein the sheet workpiece is transferred between the sputtering units by a conveyer belt or an automatic cart.

9. The method as claimed in claim 1, wherein the metal oxide includes niobium oxide and the semiconductor oxide includes silicon oxide.

10. The method as claimed in claim 1, further comprising a step of forming the sheet workpiece prior to the manufacturing steps for deposition of the multilayer film thereon.
